(19) United States
(12) Patent Application Publication
(10) Pub. No.: US 2022/0070287 A1
(43) Pub. Date: Mar. 3, 2022

(54) HOLDING STRUCTURE AND ELECTRONIC DEVICE

(71) Applicant: SHARP KABUSHIKI KAISHA, Sakai City (JP)

(72) Inventors: YOSHIKAZU TAKEMOTO, Sakai City (JP); MOTOO GOHDA, Sakai City (JP); KAZUTAKA OKUZAKO, Sakai City (JP)

(21) Appl. No.: 17/411,486

(22) Filed: Aug. 25, 2021

(30) Foreign Application Priority Data
Sep. 1, 2020 (JP) 2020-146802

(51) Int. Cl. H04M 1/04

(52) U.S. Cl. CPC H04M 1/04; H04M 1/0202

(57) ABSTRACT

A holding structure comprises a portion of a housing having the holding structure formed therein, the holding structure enabling a mounting part to be attached thereto, the portion having a fitting hole that enables the mounting part to be fitted thereto; and a regulation portion that is part of the housing, wherein the regulation portion regulates movement of the mounting part in a fall off direction in which the mounting part fails off from the fitting hole when the mounting part is fitted to the fitting hole.

### CROSS-REFERENCE TO RELATED APPLICATION

The present application. claims priority from. Japanese Patent Application Number 2020-146802, the content to which is hereby incorporated by reference into this application.

### BACKGROUND OF THE INVENTION

### Field of the Invention

The present disclosure relates to a holding structure and an electronic device.

### Description of the Related Art

Japanese Unexamined Patent Application Publication No. 2007-280835 describes a digital still camera that holds a battery in a battery compartment thereof and that enables the battery to be removed through the bottom of the body of the camera. The digital still camera described in Japanese Unexamined Patent Application Publication No. 2007-280835 has, in the body thereof, a sliding pin, a taper cam, a torsion spring, and a lock pawl which provide the structure for holding the battery.

However, the digital still camera described in Japanese Unexamined Patent Application Publication No. 2007-280835 is provided with an additional part separated from the camera body to hold the battery in the camera body. As a result, the manufacturing cost of the digital still camera increases due to the additional separate part. In addition, the size of the digital still camera increases due to the region occupied by the separate part. Accordingly, an aspect of the present disclosure aims to reduce the manufacturing cost of a product and to reduce the size of the product.

### SUMMARY OF THE INVENTION

According to an aspect of the disclosure, a holding structure includes a portion of a housing having the holding structure formed therein and enabling a mounting part to be attached thereto, where the portion has a fitting hole that enables the mounting part to be fitted thereto, and a regulation portion that is part of the housing. The regulation portion regulates movement of the mounting part in a fall off direction in which the mounting part falls off from the fitting hole when the mounting part is fitted to the fitting hole.

### BRIEF DESCRIPTION OF THE DRAWINGS

FIG. 1 is a perspective view illustrating the configuration of a holding structure of an electronic device according to a first embodiment of the present disclosure;

FIG. 2 is a perspective view of the holding structure illustrated in FIG. 1, with a mounting part removed from a fitting hole;

FIG. 3 is a cross-sectional view of the holding structure taken along line A1-A1 of FIG. 1;

FIG. 4 illustrates the configuration of a holding structure of an electronic device according to a second embodiment of the present disclosure;

FIG. 5 illustrates the configuration of a holding structure of an electronic device according to a third embodiment of the present disclosure;

FIG. 6 illustrates the configuration of a holding structure of an electronic device according to a fourth. embodiment of the present disclosure;

FIG. 7 illustrates the configuration of a holding structure of an electronic device according to the fifth embodiment or the present disclosure; and

FIG. 8 is a cross-sectional view of the holding structure taken along line A4-A4 of FIG. 7.

### DETAILED DESCRIPTION OF THE INVENTION

First Embodiment

### Configuration of Electronic Device

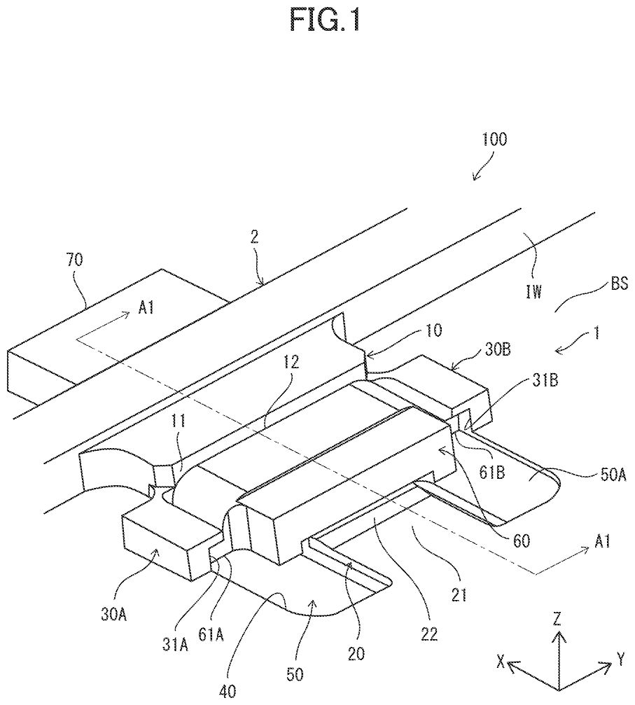

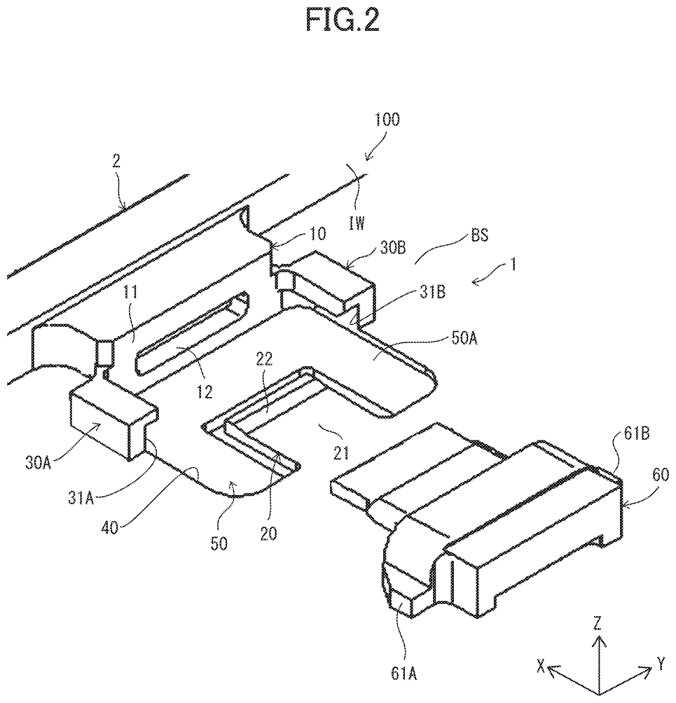

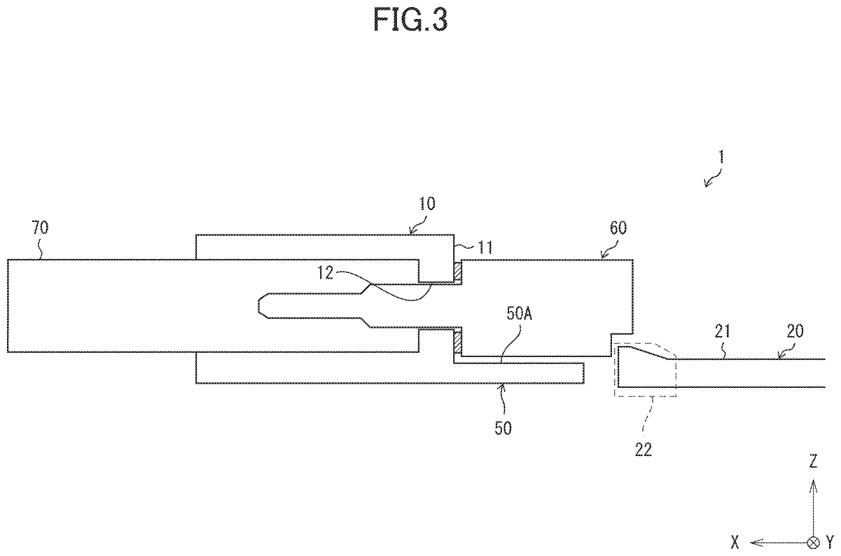

FIG. 1 is a perspective view of the configuration of a holding structure 1 of an electronic device 100 according to the first embodiment of the present disclosure. FIG. 2 is a perspective view of the holding structure 1 illustrated in FIG. 1, with a mounting part 60 removed from a fitting hole 12. FIG. 3 is a cross-sectional view of the holding structure 1 taken along line A1-A1 of FIG. 1. In FIGS. 1 to 3, the direction from a regulation portion 20 to an inner wail protrusion portion 10 is the positive direction of the X-axis, the direction from the stopper portion 30A to the stopper portion 30B is the positive direction of the Y-axis, and the direction in which the stopper portions 30A and 30B protrude from a bottom surface BS parallel to the XY plane is the positive direction of the Z-axis.

As illustrated in FIGS. 1 and 2, the electronic device 100 includes a housing 2 that has a holding structure 1. The electronic device 100 is a smartphone, but is not limited thereto. For example, the electronic device 100 may be a tablet or a personal computer (PC). The material of the housing 2 is, for example, a resin, and the housing 2 is integrally molded. The holding structure 1 has the inner wall protrusion portion 10, the fitting hole 12, the regulation portion 20, the stopper portions 30A and 30B, and a support plate 50. The holding structure 1 is formed inside the housing 2 to which a mounting part 60 is attached. The holding structure holds the mounting part 60.

The mounting part 60 is inserted and fitted into the fitting hole 12 from the inside of the housing 2 so as to be integrated into the housing 2. The mounting part 60 serves as an external connection part 70 (for example, a DSP connector that is to be connected to a plug of a universal serial bus (DSP) cable). Thus, the electronic device 100 can be connected to an external device. Alternatively, the mounting part 60 may be a part such as an earphone lack that is to be connected to an earphone or an internal camera.

The holding structure 1 is a structure for holding the mounting part 60 at the fitting position of the housing 2. As illustrated in FIGS. 1 to 3, when the external connection part 70 is connected to a mounting part 60 attached to the housing 2 from outside the electronic device 100, a force is applied to the mounting part 60 in the insertion direction. of the external connection part 70, that is, in the negative direction of the X-axis. For this reason, it is desirable that the holding structure I hold the mounting part 60 at the fitting position of the housing 2. The holding structure 1 is also a structure to regulate the movement of the mounting part 60 in the X, Y and directions when the external connection part 70 is connected to the mounting part 60.

The inner wall protrusion portion 10 is formed so as to protrude in the negative direction of the X-axis from an inner wall IW of the housing 2 extending in the Z direction. The inner wall protrusion portion 10 is formed as part of the housing 2. The inner wall protrusion portion 10 has a wall portion 11 extending in the Z direction. The wall portion 11 has one fitting hole 12 into which the mounting part 60 is to be fitted. However, the configuration is not limited thereto. For example, a plurality of fitting holes 12 may be formed in the wall portion 11. The fitting hole 12 is formed in the housing 2 so that the Y direction is the longitudinal direction. The mounting part 60 can be inserted into the fitting hole 12 in the positive direction of the X-axis. When the mounting part 60 is inserted into the fitting hole 12, the mounting part 60 is fitted to the fitting hole 12.

The regulation portion 20 is formed so as to be part of the bottom surface BS, which is part of the housing 2. That is, the regulation portion 20 is formed so as to he part of the housing 2. The regulation portion 20 protrudes in the positive direction of the X-axis. The regulation portion 20 regulates the movement of the mounting part 60 in the fall off direction, which is the direction in which the mounting part 60 that is fitted to the fitting hole 12 falls out of the fitting hole 12. The fall off direction is the negative direction of the X-axis. The regulation portion 20 is disposed away from the fitting hole 12 in the fall off direction.

The regulation portion 20 has a leaf spring 21 extending parallel to the direction from the regulation portion 20 to the fitting hole 12, that is, the positive direction of the X-axis. A surface of the leaf spring 21 that faces the positive direction of the Z-axis is the same as the bottom surface BS. As illustrated in FIG. 3, a claw portion 22 is formed at the end of the leaf spring 21 of the regulation portion 20 adjacent to the fitting hole 12. The claw portion 22 protrudes toward. the mounting part 60 that is fitted to the fitting hole 12. Note that the claw portion 22 slopes so as to gradually protrude from the leaf spring 21 as the claw portion 22 extends in the direction from the regulation portion 20 toward the fitting hole 12.

The claw portion 22 is formed on the leaf spring 21 to regulate the movement of the mounting part 60 in the fall off direction. The leaf spring 21 and the claw portion 22 are formed so as to be part of the housing 2. The leaf spring 21 has elasticity. Accordingly, the claw portion 22 is pushed down by the mounting part 60 until the mounting part 60 is completely fitted to the fitting hole 12.

In addition, when the mounting part 60 is completely fitted to the fitting hole 12, the claw portion 22 returns from the pushed-down position to the position at which the claw portion 22 regulates the movement of the mounting part 60 in the fail off direction. The pushed-down position is a position ahead of the bottom surface ES in the negative direction of the Z-axis. The position of the mounting part 60 at which the movement thereof in the fall off direction is regulated is the position before the claw portion 22 is pushed down by the mounting part 60.

More specifically, when the mounting part. 60 is inserted into the fitting hole 12, the leaf spring 21 flexes down in the negative direction of the Z-axis due to the contact of the mounting part 60 with the claw portion 22. When the mounting part 60 is completely fitted to the fitting hole 12, the regulation portion 20 regulates the movement of the mounting part 60 in the off direction by allowing the leaf spring 21 to return to the original position in the positive direction of the Z-axis.

In this way, by bringing the mounting part 60 into contact with the claw portion 22 and pushing down the claw portion 22, the mounting part 60 can be easily fitted into the fitting hole 12. In addition, when the mounting part 60 is completely fitted to the fitting hole 12, the movement of the mounting part 60 is regulated by the claw portion 22. As a result, the mounting part 60 can be avoided from falling out of the fitting hole 12.

The pair of stopper portions 30A and 30B are formed so as to protrude from the bottom surface BS in the positive direction of the Z-axis. In addition, the stopper portions 30A and 30B are formed so as to be part of the housing 2. The stopper portions 30A and 30B have concave portions 31A and 31B formed therein, respective. The mounting part 60 has a pair of protrusion portions 61A and 61B formed thereon. When the mounting part 60 are fitted to the fitting hole 12, the protrusion portions 61A and 61B formed on the mounting part 60 enter the concave portions 31A and 31B, respectively.

As a result, the stopper portions 30A and 30B cover part of the mounting part 60 by receiving the protrusion portions 61A and 61B, respectively. In this manner, the stopper portions 30A and 30B regulate the movement of the mounting part 60 in the direction perpendicular to a mounting surface 50A of the support plate 50 on which. the mounting part 60 fitted to the fitting hole 12 is disposed. The direction perpendicular to the mounting surface 50A is the positive direction of the Z-axis.

Note that instead of the stopper portions 30A and 30B, a single stopper portion may be formed on the bottom surface BS so as to cover at least part of the portion of the mounting part 60 exposed through the fitting hole 12 in the negative direction of the X-axis. Since the stopper portions 30A and 30B regulate the movement of the mounting part 60 in the direction perpendicular to the mounting surface 50A, the mounting part 60 can be avoided. from being lifted off the mounting surface 50A.

The support plate 50 is surrounded by an opening 40 because the mounting surface 50A is formed so as to be disposed away from the bottom surface BS in the negative direction of the Z-axis. In addition, the support plate 50 is separated from the regulation portion 20. When the mounting part 60 is completely fitted to the fitting hole 12, the support plate 50 supports the mounting part 60 from the negative Z-axis direction side. At. this time, the mounting part 60 is placed on the mounting surface 50A of the support plate 50.

When, the mounting part 60 is a USB connector, only a terminal portion of the mounting part 60 to be connected to the USB cable is inserted into the fitting hole 12. In addition, when the USB cable is connected to the mounting part 60 from the outside of the electronic device 100, the regulation portion 20 regulates the movement of the mounting part 60 due to the load applied to the mounting part 60 in the negative direction of the X-axis.

The mounting part 60 has the pair of protrusion. portions 61A and 61B. The protrusion portions 61A and 61B protrude in a direction that intersects the direction extending from the regulation portion 20 to the fitting hole 12 when the mounting part 60 is fitted to the fitting hole 12. That is, the protrusion portions 61A and 61B protrude in the Y direction representing a direction intersecting the positive direction of the X-axis. In addition, the protrusion portions 61A and 61B are formed on the portion of the mounting part 60 that is exposed through the fitting hole 12 in the negative direction of the X-axis when the mounting part 60 is fitted to the fitting hole 12.

As described above, the fitting hole 12 to which the mounting part 60 is fitted is formed in the housing 2, and the regulation portion 20 that regulates the movement of the mounting part 60 is formed so as to be part of the housing 2. For this reason, the use of an additional part that is separated from the housing 2 and that maintains the mounting part 60 at the fitting position in the housing 2 can be avoided. That is, the structure to maintain the mounting part 60 at the fitting position in the housing 2 is completed by the housing 2 itself. Non-use of an additional separate part can reduce the manufacturing cost of the product with the housing 2. In addition, non-use of the area occupied by the additional separate part reduces the size of the product by the amount of the area.

### Second Embodiment

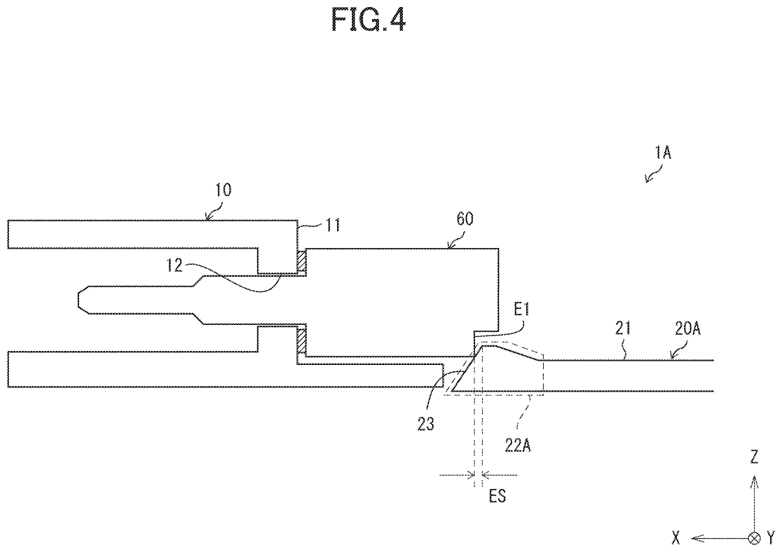

The second embodiment of the present disclosure is described below. For convenience of description, members having the same function as those described in first embodiment are identified with the same reference numerals, and description of the members is not repeated. FIG. 4 illustrates the configuration of a holding structure 1A of an electronic device according to the second. embodiment of the present disclosure.

As illustrated in FIG. 4, unlike the holding structure 1, the holding structure 1A includes a regulation. portion 20A instead of the regulation portion 20. The leaf spring 21 of the regulation portion 20A has a claw portion 22A formed at an end adjacent to the fitting hole 12. At the end of the claw portion 22A adjacent to the fitting hole 12, an inclined surface 23 is formed so as to cant toward the mounting part 60 as the inclined surface 23 extends in the fall off direction.

When the mounting part 60 is fitted to the fitting hole 12 the force generated by the claw portion 22A. that returns from the pushed-down position to the position at which the claw portion 22A regulates, the movement of the mounting part 60 is applied by the inclined surface 23 in the direction in which the mounting part 60 is pressed into the fitting hole 12. This configuration facilitates contact of the mounting part 60 with the claw portion 22A, and the mounting part 60 is guided into the fitting hole 12. As a result, backlash between the mounting part 60 and the regulation portion 20A can be reduced.

In. addition, even if an error in dimension between the design value and the actual value of each of the mounting part 60 and the regulation portion 20A occurs, the mounting part 60 can be in contact with the claw portion 22A, since the inclined surface 23 is formed on the claw portion 22A. As a result, the movement of the mounting part 60 can be stably regulated by the regulation portion 20A.

As the leaf spring 21 moves in the Z direction, the claw portion 22A also moves in the Z direction. For this reason, it is desirable to avoid the mounting part. 60 from getting caught on the claw portion 22A when the mounting part 60 is inserted into the fitting hole 12. Accordingly, the regulation portion 20A is disposed so that a gap ES is formed between an end E1 of the mounting part 60 adjacent to the regulation portion 20A and the upper end of the claw portion 22A.

At this time, if, in the first embodiment, the regulation portion 20 does not have the inclined surface 23 and a gap is formed between the claw portion 22 and the mounting part 60, backlash occurs between the mounting part 60 and the regulation portion 20 when the mounting part 60 is fitted to the fitting hole 12.

In contrast, the case is discussed where the regulation portion 20 is disposed such that a gap between the mounting part 60 and the regulation portion 20 is not generated in order to avoid the occurrence of backlash between the two parts. In this case, if there is an error in dimension between the design value and the actual value for each of the mounting part 60 and the regulation portion 20, the regulation portion 20 may push up the mounting part 60 that is fitted to the fitting hole 12 in the positive direction of the Z-axis.

Accordingly, it may be difficult for the regulation portion 20 to regulate the movement of the mounting part 60. According to the second embodiment, since the claw portion 22A has the inclined surface 23 formed thereon, the occurrence of backlash between the mounting part 60 and the regulation portion 20A can be avoided. In addition, the positional accuracy of the mounting part 60 can be improved.

### Third Embodiment

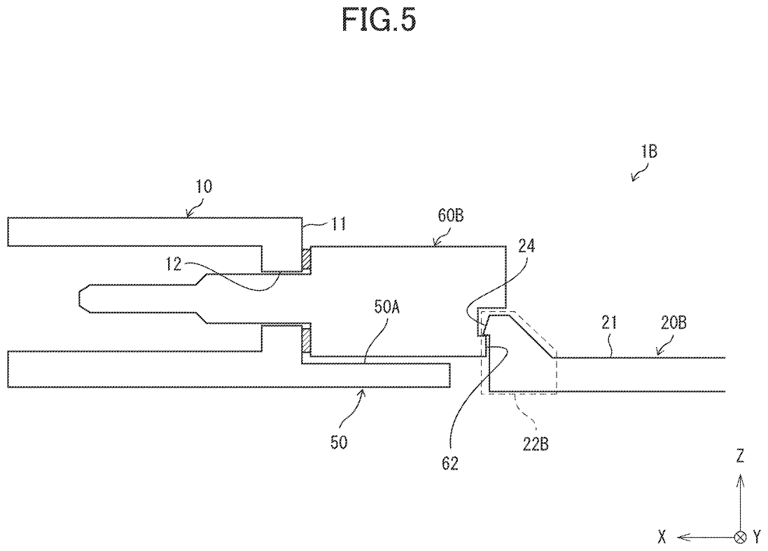

The third embodiment of the present disclosure is described below. For convenience of description, members having the same functions as those described in first and second embodiments are identified with the same reference numerals, and description of the members is not repeated. FIG. 5 illustrates the configuration of a holding structure 1B of an electronic device according to the third embodiment of the present disclosure.

As illustrated in FIG. 5, unlike the holding structure 1, the holding structure 13 has a regulation portion 20B instead of the regulation portion 20. The leaf spring 21 of the regulation portion 20B has a claw portion 22B at an end thereof adjacent to the fitting hole 12. The claw portion 22B has, at an end thereof adjacent to the fitting hole 12, an engagement portion 24 protruding toward a mounting part 60B fitted to the fitting hole 12.

By engaging with a convex portion 62 formed on the end of the mounting part 60B facing the fall off direction, the engagement portion 24 regulates the movement of the mounting part 60B in the direction perpendicular to the mounting surface 50A of the support plate 50 having the mounting part 60B placed. thereon. In this manner, the movement of the mounting part 60B in the direction perpendicular to the mounting surface 50A is regulated by the engagement portion 24. As a result, the mounting part 60B can be avoided from being lifted off the mounting surface 50A.

In addition, since engagement of the engagement portion 24 with the convex portion 62 can stop the mounting part 60B from being lifted off the mounting surface 50A, the above-mentioned stopper portions 30A and 30B can be removed from the holding structure 1B. As a result, the holding structure 1B does not necessarily have to have the stopper portions 30A and 30B.

### Fourth Embodiment

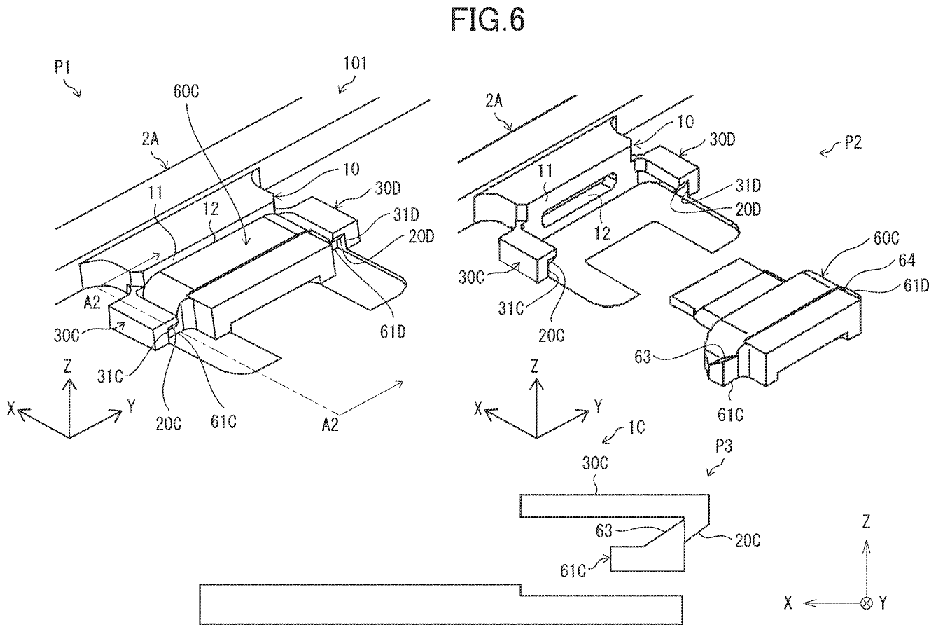

The fourth embodiment of the present disclosure is described below. For convenience of description, members having the same functions as those described in first to third embodiments are identified with the same reference numerals, and description of the members is not repeated. FIG. 6 illustrates the configuration of a holding structure 1C of an electronic device according to the fourth embodiment of the present disclosure.

Reference numeral P1 in FIG. 6 indicates a perspective view of the holding structure 10 with the mounting part 60C fitted into the fitting hole 12, and reference numeral P2 in FIG. 6 indicates a perspective view of the holding structure 1C with the mounting part 60C removed. from the fitting hole 12. Reference numeral P3 in FIG. 6 indicates a cross-sectional view of the holding structure 10 indicated by reference numeral P1 in FIG. 6 taken along line A2-A2.

As indicated by reference numerals P1 and P2 in FIG. 6, unlike the holding structure 1, the holding structure 10 does not include the regulation portion 20. Concave portions 31C and 31D are formed in stopper portions 30C and 30D, respectively. When the mounting part 60C is completely fitted to the fitting hole 12, a pair of protrusion portions 61C and 61D formed on the mounting part 60C enter the concave portions 31C and 31D, respectively.

The concave portions 31C and 31D of the stopper portions 30C and 30D have hooking portions 20C and 20D formed therein, respectively. The hooking portions 20C and 20D are formed so as to be part of a housing 2A. The hooking portions 20C and 20D are regulation portions that regulate movement of the mounting part 60C in the fall off direction when the mounting part 60C is fitted to the fitting hole 12. A particular example of the regulation portion is described below.

As indicated by reference numeral P3 in FIG. 6, when the mounting part 60C is fitted to the fitting hole 12, the hooking portion 20C is hooked on a convex portion 63 that is an end portion of the mounting part 60C in the fall off direction. Since the hooking portion 20C of the stopper portion 30C is hooked on the convex portion 63 of the mounting part 60C with the mounting part 60C fitted to the fitting hole 12, the movement of the mounting part 60C in the fall off direction can be regulated.

Note that like the hooking, portion 20C, the hooking portion 20D is hooked on a convex portion 64 formed on the protrusion portion 61D of the mounting part 60C. That is, the configuration of the hooking portion 20D is the same as that of the hooking portion 20C. In addition, since the movement of the mounting part 60C in the fall off direction can be regulated by using the hooking portions 20C and 20D and the convex portions 63 and 64, the need for the above-mentioned regulation portion 20 can be avoided. For this reason, the holding structure 1C does not necessarily have to have the regulation portion 20.

### Fifth Embodiment

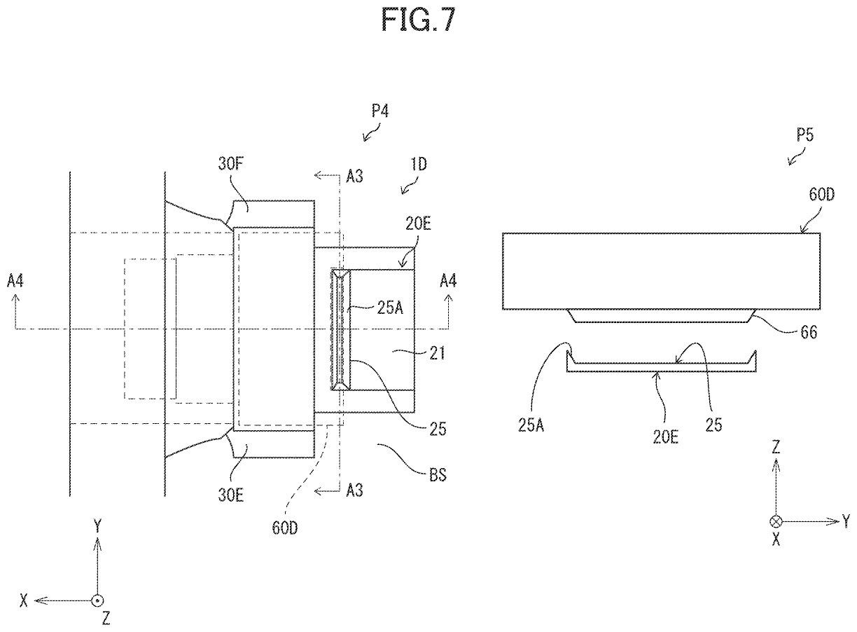

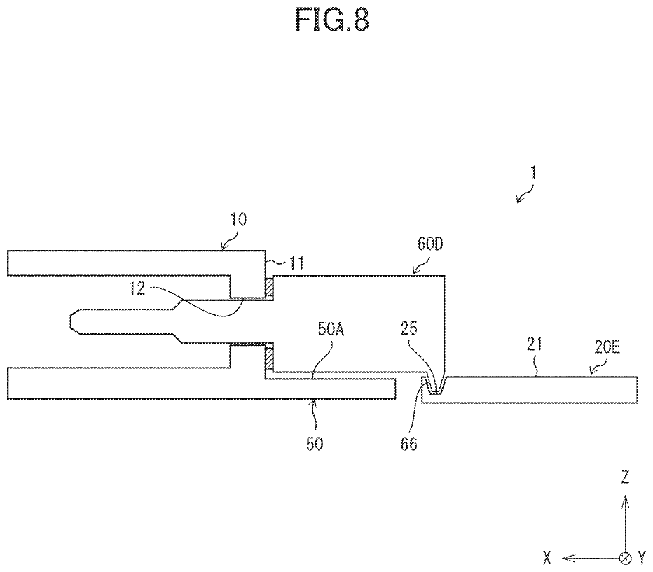

The fifth embodiment of the present disclosure is described below. For convenience of description, members having the same functions as those described in first to fourth embodiments are identified with the same reference numerals, and description of the members is not repeated. FIG. 7 illustrates the configuration of a holding structure 1D of an electronic device according to the fifth embodiment of the present disclosure. FIG. 8 is a cross-sectional view of the holding structure 1D taken along line A4-A4 of FIG.

Reference numeral P4 in FIG. 7 indicates a plan view of the holding structure 1D viewed in the positive direction of the Z-axis. Reference numeral P5 in FIG. 7 indicates a cross-sectional view of the holding structure 1D indicated by reference numeral P4 in FIG. 7, taken along line A3-A3. Reference numeral P5 in FIG. 7 indicates the case where a regulation portion 20E and a mounting part 60D are separated from. each other. As can be seen from FIGS. 7 and 8, unlike the holding structure 1, the holding structure 1D includes the regulation portion 20E instead of the regulation portion 20.

A concave portion 25 is formed at the end of the leaf spring 21 of the regulation portion 20E adjacent o the fitting hole 12. The concave portion 25 has an inclined surface 25A so as to taper in the negative direction of the Z-axis. The mounting part 60D has a claw portion 66 extending in the negative direction of the Z-axis at the end thereof facing the fail off direction. When the mounting part 60D is fitted to the fitting hole 12, the claw portion 66 is fitted to the concave portion 25.

The inclined surface 25A formed in the concave portion 25 makes it easier for the claw portion 66 to be fitted to the concave portion 25. In addition, the claw portion 66 fitted to the concave portion 25 can regulate the movement of the mounting part 60D relative to the fitting hole 12 in the Y direction. Instead of the stopper portions 30A and 30B, wall portions 30E and 30F may be formed on the bottom surface BS. Each of the wall portions 30E and 30F does not have a concave portion formed therein. The wall portions 30E and 30F are provided to regulate the movement of the mounting part 60D relative to the fitting hole 12 in the Y direction. These configurations can improve the positioning accuracy of the mounting part 60D.

The above description has been made with reference to the case where the concave portion 25 is formed in the regulation portion 20E and the claw portion 66 is formed in the mounting part 60D. However, conversely, the claw portion 66 may be formed in the regulation portion 20E, and the concave portion 25 may be formed in the mounting part 60D. Even in this case, the claw portion 66 is fitted to the concave portion 25 and, thus, the movement of the mounting part 60D relative to the fitting hole 12 in the Y direction can be regulated.

### SUMMARY

According to a first aspect of the present disclosure, a holding structure is formed inside a housing that enables a mounting part to be attached thereto. The holding structure holds the mounting part. The holding structure includes a fitting hole formed in the housing, where the mounting part is fitted to the fitting hole, and a regulation portion that is part of the housing. The regulation portion regulates movement of the mounting part in a fall off direction in which the mounting part falls off from the fitting hole when the mounting part is fitted to the fitting hole.

According to a second aspect, the holding structure according to the first aspect may further include a stopper portion that is part of the housing. The stopper portion may regulate movement of the mounting part in a direction perpendicular to a mounting surface on which the mounting part is to be placed when the mounting part is fitted to the fitting hole.

According to a third aspect, in the holding structure according to the first or second aspect, the regulation portion may be disposed away from the fitting hole in the fall off direction. A claw portion may be formed at an end of the regulation portion adjacent to the fitting hole, and the claw portion may protrude toward the mounting part. The claw portion may be pushed down by the mounting part until the mounting part is completely fitted to the fitting hole. When the mounting part is completely fitted to the fitting bole, the claw portion may return from a pushed-down position to a position at which the claw portion regulates the movement of the mounting part in the fall off direction.

According to a fourth aspect, in the holding structure according to the above-described third aspect, at the end of the claw portion adjacent to the fitting hole, an inclined surface may be formed so as to cant toward the mounting part as the inclined surface extends in the fall off direction.

According to a fifth aspect, in the holding structure according to the above-described third aspect, the claw portion may have an engagement portion formed at an end thereof adjacent to the fitting hole, and the engagement portion may engage with an end of the mounting part facing the fall off direction with the mounting part being fitted to the fitting hole and regulate movement of the mounting part in a direction perpendicular to a mounting surface on which the mounting part is to be placed.

According to a sixth aspect, in the holding structure according to the above-described second aspect, the regulation portion may be a hooking portion formed in the stopper portion, and the hooking portion may be hooked on an end of the mounting part facing the fall off direction with the mounting part being fitted to the fitting hole.

According to a seventh aspect, in the holding structure according to the above-described first aspect, the regulation portion may be disposed. away from :he fitting hole in the fall off direction. At an end of the regulation portion adjacent to the fitting hole, a concave portion may be formed so as to be fitted to a claw portion formed at an end of the mounting part facing the fall off direction. According to an eighth aspect, an electronic device may have the holding structure.

The present disclosure is not limited to each of the above-described embodiments, but various changes can be made within the scope of the claims. In addition, embodiments obtained by combining the techniques described in different embodiments as appropriate are also encompassed by the technical scope of the present disclosure. Furthermore, new technical features can be constructed by combining the techniques described in the embodiments in any way.

It should be understood by those skilled in the art that various modifications, combinations, sub-combinations and alterations may occur depending on design requirements and other factors insofar as they are within the scope of the appended claims or the equivalents thereof.

What is claimed is:

1. A holding structure comprising:
a portion of a housing having the holding structure formed therein, the holding structure enabling a mounting part to be attached thereto, the portion having a fitting hole that enables the mounting part to be fitted thereto; and
a regulation portion that is part of the housing,
wherein the regulation portion regulates movement of the mounting part in a fail off direction in which the mounting part falls off from the fitting hole when the mounting part is fitted to the fitting hole.

2. The holding structure according to claim 1, further comprising:
a stopper portion that is part of the housing, the stopper portion regulating movement of the mounting part in a direction perpendicular to a mounting surface on which the mounting part is to he placed when the mounting part is fitted to the fitting hole.

3. The holding structure according to claim 1, wherein the regulation portion is disposed away from the fitting hole in the fall off direction,
wherein a claw portion is formed at an end of the regulation portion adjacent to the fitting hole, and the claw portion protrudes toward the mounting part,
wherein the claw portion is pushed down by the mounting part until the mounting part is completely fitted to the fitting hole, and
wherein when the mounting part is completely fitted to the fitting hole, the claw portion returns from a pushed-down position to a position at which the claw portion regulates the movement of the mounting part in the fall off direction.

4. The holding structure according to claim 3, wherein at the end of the claw portion adjacent to the fitting hole, an inclined surface is formed so as to cant toward the mounting part as the inclined surface extends in the fall off direction.

5. The holding structure according to claim 3, wherein the claw portion has an engagement portion formed at an end thereof adjacent to the fitting hole, and
wherein the engagement portion engages with an end of the mounting part facing the fall off direction with the mounting part being fitted to the fitting hole and regulates movement of the mounting part in a direction perpendicular to a mounting surface on which the mounting part is to be placed.

6. The holding structure according to claim 2, wherein the regulation portion is a hooking portion formed in the stopper portion, and
wherein the hooking portion is hooked on an end of the mounting part facing the fall off direction with the mounting part being fitted to the fitting hole.

7. The holding structure according to claim 1, wherein the regulation portion is disposed away from the fitting hole in the fall off direction, and
wherein at an end of the regulation portion adjacent to the fitting hole, a concave portion is formed so as to be fitted to a claw portion formed at an end of the mounting part facing the fall off direction.

8. An electronic device comprising:
the holding structure according to claim 1.
